(19) United States
(12) Patent Application Publication
(10) Pub. No.: US 2022/0165852 A1
(43) Pub. Date: May 26, 2022

(54) METHODS AND APPARATUS FOR METAL FILL IN METAL GATE STACK

(71) Applicant: Applied Materials, Inc., Santa Clara, CA (US)

(72) Inventors: Srinivas GANDIKOTA, Santa Clara, CA (US); Yixiong YANG, Santa Clara, CA (US); Jacqueline S. WRENCH, San Jose, CA (US); Luping LI, Santa Clara, CA (US); Yong YANG, Mountain View, CA (US); Seshadri GANGULI, Sunnyvale, CA (US)

(21) Appl. No.: 17/529,948

(22) Filed: Nov. 18, 2021

Related U.S. Application Data
(60) Provisional application No. 63/117,385, filed on Nov. 23, 2020.

(51) Int. Cl. H01L 29/40; H01L 29/49; C23C 28/02; C23C 28/00; C23C 16/455

(52) U.S. Cl. CPC H01L 29/401; H01L 29/4958; H01L 29/4966; H01L 29/4908; H01L 21/28088; C23C 28/322; C23C 28/34; C23C 28/341; C23C 16/45544; C23C 28/023

(57) ABSTRACT

A method of filling a feature in a semiconductor structure includes forming a barrier layer in the feature by one of atomic layer deposition (ALD), chemical vapor deposition (CVD), or physical vapor deposition (PVD); wherein the barrier layer is one of cobalt (Co), molybdenum (Mo), molybdenum nitride (MoN) plus Mo, titanium (Ti), titanium aluminum carbide (TiAlC), or titanium nitride (TiN); and forming a metal layer in the feature and over the barrier layer by one of ALD or CVD; wherein the metal layer is one of aluminum (Al), Co, Mo, ruthenium (Ru), or tungsten (W).

### CROSS-REFERENCE TO RELATED APPLICATIONS

This application claims benefit of U.S. provisional patent application Ser. No. 63/117,385, filed Nov. 23, 2020, which is herein incorporated by reference in its entirety.

### FIELD

Embodiments of the present disclosure generally relate to thin film fabrication techniques.

### BACKGROUND

In previous (i.e., larger) nodes, the industry has used physical vapor deposition (PVD) of titanium (Ti) followed by chemical vapor deposition (CVD) of aluminum (Al) to achieve a metal fill for metal gate stack applications. However, the inventors have observed that the foregoing process cannot meet the requirements of gapfill anymore, due, for example, to the challenges from new applications and structures such as three dimensional (3D) FinFET or gate all around (GAA) structures with the device scaling to smaller feature sizes (e.g., smaller nodes).

To illustrate the foregoing, FIG. 1 schematically depicts a substrate 100 having a base layer 102 in which a feature 104 is formed. A barrier layer 106 is formed over the top surface of the base layer 102, including upon surfaces of the feature 104 (e.g., along sidewalls and bottom of the feature 104). A metal layer 108 is subsequently formed atop the barrier layer 106. A seam 110 is observed within the feature 104 after the feature is filled with the barrier layer 106 and the metal layer 108. The presence of such a seam is undesired because seams are detrimental to subsequent processing, such as chemical mechanical planarization (CMP) or etch processes. For example, etchant or CMP polishing slurry can undesirably diffuse into the feature through the seam. In addition, the inventors have observed that such seams can also undesirably contribute to the increase of stack resistance. Therefore, the inventors have provided embodiments of methods and apparatus for filling features which can be extended into more challenging 3D structures such as FinFET and GAA structures.

### SUMMARY

Embodiments of methods and apparatus for filling features are provided herein. Specifically, embodiments of the present disclosure advantageously provide methods and apparatus to accomplish different gapfill schemes, which are FinFET/GAA structure friendly. The disclosed processes described herein can be used in smaller structures as well as in more complex structures, such as 3D structures, such as in FinFET and GAA applications, amongst others.

In addition, embodiments of methods and apparatus provided herein may also be used to fill features with reduced or eliminated seams. Specifically, embodiments of the present disclosure advantageously provide methods and apparatus to minimize, reduce or eliminate seam formation while filling a feature. The metal films were demonstrated to provide good gapfill with minimal electrical performance impact. Moreover, since the underlying TiN material properties are preserved, the process can be more easily integrated in a multi-chamber processing tool, as described below.

In some embodiments, a method of filling a feature in a semiconductor structure includes forming a barrier layer in the feature by one of atomic layer deposition (ALD), chemical vapor deposition (CVD), or physical vapor deposition (PVD); wherein the barrier layer is one of cobalt (Co), molybdenum (Mo), molybdenum nitride (MoN) plus Mo, titanium (Ti), titanium aluminum carbide (TiAlC), or titanium nitride (TiN); and forming a metal layer in the feature and over the barrier layer by one of ALD or CVD; wherein the metal layer is one of aluminum (Al), Co, Mo, ruthenium (Ru), or tungsten (W).

In some embodiments, a gapfill in a feature of a semiconductor structure includes a barrier layer in the feature; wherein the barrier layer is one of: molybdenum (Mo), molybdenum nitride (MoN) plus Mo, titanium (Ti), titanium aluminum carbide (TiAlC), or titanium nitride (TiN), with each having been formed by atomic layer deposition (ALD); or cobalt (Co) or Ti, with each having been formed by chemical vapor deposition (CVD), and a metal layer in the feature and over the barrier layer; wherein the metal layer is one of: Mo or tungsten (W), with each having been formed by ALD; or aluminum (Al), Co, or ruthenium (Ru), with each having been formed by CVD; wherein the metal layer is seamless.

In some embodiments, a system for forming a gapfill in a feature of a semiconductor structure includes an apparatus configured to form—by one of atomic layer deposition (ALD), chemical vapor deposition (CVD), or physical vapor deposition (PVD)—in the feature a barrier layer that is one of cobalt (Co), molybdenum (Mo), molybdenum nitride (MoN) plus Mo, titanium (Ti), titanium aluminum carbide (TiAlC), or titanium nitride (TiN); and an apparatus configured to form—by one of ALD or CVD—in the feature and over the barrier layer a metal layer that is one of aluminum (Al), Co, Mo, ruthenium (Ru), or tungsten (W); wherein the barrier layer and the metal layer are the gapfill; wherein the gapfill is seamless.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a schematic view of a prior art feature filled in a substrate and containing a seam.

FIGS. 2A-2F respectively depict non-limiting exemplary structures that can be fabricated using methods and apparatus in accordance with the present disclosure.

FIG. 3 is a flow chart of a method of forming a semiconductor structure having a gapfill in a feature in accordance with embodiments of the present disclosure.

FIGS. 4A-4E depict cross-sectional views of forming a semiconductor structure having a gapfill in a feature in accordance with embodiments of the present disclosure.

FIG. 5 depicts a schematic top-view diagram of an illustrative multi-chamber processing system in accordance with embodiments of the present disclosure.

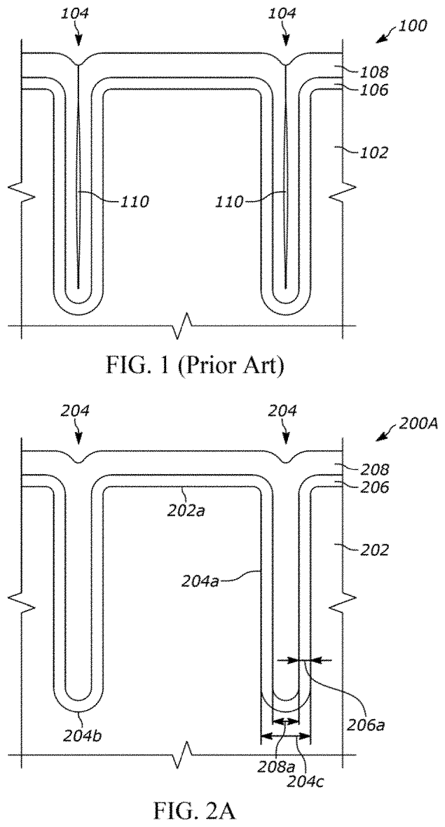

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods and apparatus for filling features are provided herein. Specifically, embodiments of the present disclosure advantageously provide methods and apparatus to accomplish different gapfill schemes, which are FinFET/GAA structure friendly. The disclosed processes described herein can be used in smaller structures as well as in more complex structures, such as 3D structures, such as in FinFET and GAA applications, amongst others. The gapfill can be without or essentially no seam formation.

As used herein, the terms “without seam”, “seamless” and the like are intended to mean “no seam” and/or “essentially no seam”.

As used herein, the term “essentially no seam” and the like is intended to include structures where a seam is detectable by transition electron microscopy (TEM), but wherein the seam has a width of no more than about 3 angstroms throughout the length of the feature.

Alternatively or additionally, as used herein, the term “essentially no seam” and the like is intended to mean that there is a seam detectable by transition electron microscopy but the seam causes, if at, minimal electrical performance impact on a semiconductor having a feature that is filled.

As used herein, the term “minimal electrical performance impact” and the like is intended to mean that a semiconductor experiences, upon filling a feature therein, a change in flat-band voltage (Vfb) of not more than about 0% to about 5% (e.g., from about 0 to about 5%) and/or a change in equivalent oxide thickness (EOT) of not more than 5% (e.g., from about 0 to about 5%).

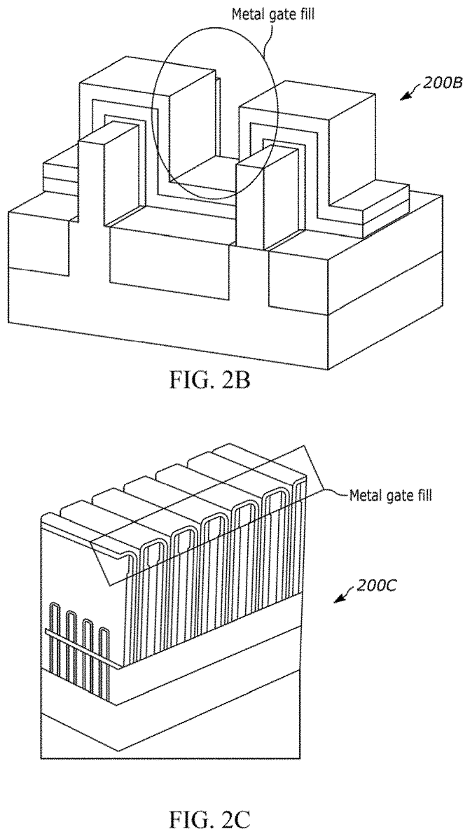

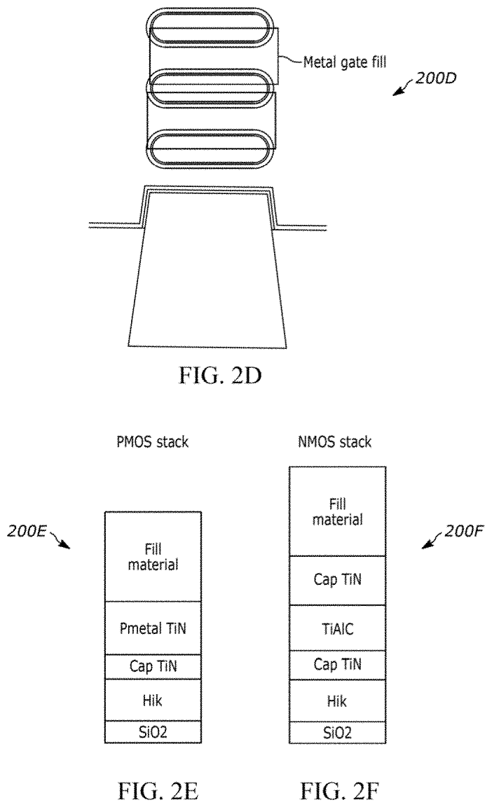

FIGS. 2A-2F respectively depict exemplary structures that can be fabricated using methods and apparatus in accordance with the present disclosure. In embodiments, a gapfill in a feature of a semiconductor structure can include a barrier layer and a metal contact layer thereon in accordance with embodiments of the present disclosure. The gapfill can be seamless.

FIG. 2A depicts schematically a substrate 200A having a base layer 202 in which a feature 204 is formed according to embodiments of the present disclosure. The base layer 202 can be a layer of a singular material or compound. Alternatively, the base layer 202 can include a plurality of layers (e.g., a film stack), such as may be present during fabrication of a device such as a transistor or the like (e.g., a portion of a FinFET structure, a GAA structure, a PMOS stack, an NMOS stack, or the like). The feature 204 can generally be the space between adjacent sidewalls 204a of the base layer 202, and which space can extend vertically to a bottom 204b of the feature. For example, the feature 204 can be a trench, via, or the like.

In embodiments, a barrier layer 206 can be formed over a top surface 202a of the base layer 202, and upon other surfaces of the feature 204 (e.g., on and along sidewalls 204a and bottom 204b of the feature 204). The barrier layer 206 can generally be deposited to form a conformal layer atop the base layer 202 and within the feature 204. The barrier layer 206 can be one layer of a singular material or compound. Alternatively, the barrier layer 206 can include a plurality of layers.

In embodiments, the barrier layer 206 can be layer of titanium (Ti) deposited by atomic layer deposition (ALD), chemical vapor deposition (CVD), or physical vapor deposition (PVD); titanium nitride (TiN) deposited by ALD; titanium aluminum carbide (TiAlC) deposited by ALD; cobalt (Co) deposited by CVD; molybdenum (Mo) deposited by ALD; or molybdenum nitride (MoN) deposited by ALD with ALD Mo deposited atop the ALD MoN. In embodiments, the barrier layer 206 may be a combination of one or more of the foregoing.

In embodiments, the barrier layer 206 may have a total volume in the feature 204 that is about 5% to about 95% of the total volume of the unfilled feature 204. In embodiments, the barrier layer 206 may have a thickness 206a in the feature 204 which is from about 5% to about 95% of a width/diameter (i.e., critical dimension) 204c of the feature 204.

In embodiments, a metal or contact layer 208 can be subsequently formed atop the barrier layer 206. The metal layer 208 may extend in and over the feature 204, and over the top surface 202a of the base layer 202. Thereby, the metal layer 208 can serve as an electrical contact layer. The metal layer 208 can one of aluminum (Al) deposited by CVD, cobalt (Co) deposited by CVD, molybdenum (Mo) deposited by ALD, ruthenium (Ru) deposited by CVD, or tungsten (W) deposited by ALD. In embodiments, the metal layer 208 may be a combination of one or more of the foregoing. The metal layer 208 may be seamless and, thus, the gapfill (i.e., the combined barrier and metal layers 206, 208) may be seamless.

In embodiments, the metal layer 208 may have a total volume in the feature that is about 5% to about 95% of the total volume of the unfilled feature 204. In embodiments, the metal layer 208 may have a thickness 208a in the feature 204 which is from about 5% to about 95% of the width/diameter (i.e., critical dimension) 204c of the feature 204.

In embodiments, a particular metal layer 208 employed can be dependent upon a particular barrier layer 206 employed. For example, the following table depicts exemplary combinations of a barrier layer 206 and a metal layer 208 to form the gapfill:

| Barrier Layer 206 | Metal Layer 208 |
|---|---|
| Co (CVD) | CVD Al |
| Mo (ALD) | CVD Al |
| MoN (ALD) + Mo (ALD) | CVD Al |
| Ti (ALD, CVD, PVD) | CVD Al |
| TiAlC (ALD) | TiCl₄ treat + Al, cyclic deposition |
| | CVD Al |
| | CVD Co |
| | ALD Mo |
| | CVD Ru |
| TiN (ALD) | TiCl₄ treat + Al, cyclic deposition |
| | CVD Co |
| | ALD Mo |
| | CVD Ru |
| | ALD W |

In embodiments where the metal layer 208 is an Al layer, the Al layer can be deposited by chemical vapor deposition (CVD). For example, an Al film can be deposited on the barrier layer 206 using a CVD process at a temperature of about 100-300 degrees Celsius, such as at about 120-180 degrees Celsius, at a pressure of about 1-50 Torr, and for a reaction time of about 20 seconds. Suitable precursors for the Al deposition include triethylaluminum (TEA), dimethylaluminum hydride (DMAH), and trimethylaluminum (TMA).

In embodiments wherein the barrier layer 206 is a TiAlC or a TiN layer, and wherein the metal layer 208 is an TiCl₄+Al layer, the metal layer 208 can be formed by a cyclic process including exposing the substrate to TiCl₄ at a temperature of about 100 to about 450 degrees Celsius, at a pressure of about 1 to about 50 Torr. That can be followed by Al CVD deposition using the CVD process noted above for an Al metal layer 208. The cyclic process can be repeated as desired to fill the feature 204.

In embodiments wherein the barrier layer 206 or the metal layer 208 is a Co layer, the Co layer can be deposited by CVD or plasma enhanced CVD (PECVD). For example, a Co film can be deposited on the base layer 202 (to form the barrier layer 206) or on the barrier layer 206 (to form the metal layer 208) using a CVD or PECVD process at about 100 to about 300 degrees Celsius, at a pressure of about 1 to about 50 Torr. Suitable precursors for the Co deposition include di-cobalt hexacarbonyl tert-butylacetylene (CCTBA).

In embodiments wherein the barrier layer 206 is a Mo layer or a MoN+Mo layer, or wherein the metal layer 208 is a Mo layer, the Mo or MoN+Mo layer can be deposited using atomic layer deposition (ALD). For example, a Mo or MoN film can be deposited on the barrier layer 206 using an ALD process that exposes the substrate to a molybdenum precursor and a reactant to a form bulk molybdenum film. In some embodiments, the ALD process can be performed at a temperature of about 350-600 degrees Celsius, for example, at about 400 to about 600 degrees Celsius, at a pressure of about 1 to about 50 Torr, and for a suitable reaction time to form a film to a desired thickness. A Mo film, as described above, can then be deposited on the MoN film.

For example, a Mo film alone can be deposited on the barrier layer 206 using an ALD process at a temperature of about 350 to about 600 degrees Celsius, for example, at about 400 to about 600 degrees Celsius, at a pressure of about 1 to about 50 Torr.

In another example, a MoN film can be deposited on the barrier layer 206 using an ALD process at a temperature of about 350 to about 600 degrees Celsius, for example, at about 400 to about 600 degrees Celsius, at a pressure of about 1 to about 50 Torr. A Mo film, as described above, can then be deposited on the MoN film.

Suitable precursors for the Mo or MoN+Mo deposition include any suitable molybdenum-containing compound that can react with (i.e., adsorb or chemisorb onto) the substrate surface to leave a molybdenum-containing species on the substrate surface. In one or more embodiments, the molybdenum precursor comprises one or more of molybdenum chloride (MoCl₅), molybdenum fluoride (MoF6), molybdenum iodide (MoI₆), molybdenum bromide (MoBr₃), molybdenum hexacarbonyl (Mo(CO)₆), molybdenum dichloride dioxide (MoO₂Cl₂), molybdenum oxytetrachloride (MoOCl₄), tetrakis(dimethylamino) molybdenum(IV), and bis(tert-butylimido)-bis(dimethylamido) molybdenum. Suitable reactants for the Mo or MoN+Mo deposition include hydrogen gas (H₂) or 1-methyl-3,6-bis(trimethylsilyl)-1,4-cyclohexadiene (CHD).

In embodiments wherein the metal layer 208 is a ruthenium (Ru) layer, the Ru layer can be deposited by CVD. For example, a Ru film can be deposited on the barrier layer 206 using a CVD process using a ruthenium precursor and a catalyst at about 200 to about 500 degrees Celsius, for example about 250 to about 350 degrees Celsius, at about 1 to about 50 Torr.

Suitable Ru precursors include Ru-containing gases having a diene, such as p-cymene Ru hexadiene, or p-cymene Ru cyclohexadiene. Suitable catalysts include alkyl halide, such as alkyl iodide, alkyl bromide, or the like. The inventors have observed that a seamless gapfill can be obtained by improving the nucleation of the deposited Ru film and decreasing film roughness using the processes as described herein.

In some embodiments, the Ru deposition process (Ru precursor soak time, Catalyst soak time and deposition temperature) is optimized for minimal roughness.

In some embodiments, the Ru deposition process includes pre-soaking the liner with catalyst at high pressure, such as at least about 20 Torr, for a duration of about 10 seconds to about 60 seconds. In some embodiments, the catalyst presoaking followed by 1 cycle of Ru deposition can be repeated, for example, up to 5 cycles.

In some embodiments, no vacuum break is provided between barrier layer and Ru deposition processes to avoid or minimize risk of oxygen contamination of the barrier layer.

In some embodiments where there is oxygen present on the barrier layer surface, for example due to a vacuum break, the amount of 0 on the barrier layer surface can be eliminated or decreased by pre-treatment by exposing the barrier layer surface to a nitrogen (N*) or hydrogen (H*) radical or direct plasma. For example, the barrier layer can be exposed to an inductively coupled plasma including an H₂ or H₂/N₂ mixture and biased substrate support to react out O from the barrier layer surface. For example, about 400 to 900 W plasma power can be provided to provide the plasma and about 50 to about 300 W bias power can be provided to the substrate support.

In some embodiments, the deposited film is annealed for grain growth. The grain growth causes the seam between two surfaces with very small gap to heal. The annealing can be done at a temperature less than 450 C for about 5 to about 30 minutes.

In some embodiments wherein the metal layer 208 is a tungsten (W) layer, the W layer can be deposited by ALD. For example, a W film can be deposited on the barrier layer 206 using a ALD process at about 350 to about 500 degrees Celsius, at about 1 to about 50 Torr. Suitable precursors include WF₆, WCl₅, WCl₆.

In embodiments wherein the barrier layer 206 is a Ti layer or a TiN layer, the Ti layer can be deposited by a suitable ALD, CVD, or PVD process and the TiN layer can be formed by a suitable ALD process. Suitable ALD processes can, for example, be performed at a temperature of about 100 to about 400 degrees Celsius, at a pressure of about 1 to about 50 Torr. Suitable Ti precursors include TiCl₄, and suitable reactants include CHD. Suitable TiN precursors include TiCl₄ and TDMAT, and suitable reactants include NH₃ and N₂H₄.

A suitable plasma enhanced CVD process can, for example, be performed at a temperature of about 300 to about 700 degrees Celsius, at a pressure of about 1 to about 200 Torr. Plasma can be formed and/or maintained using about 100 to about 1000 W of RF energy at a frequency of about 350 kHz to about 2 MHz. Suitable process gases include TiCl₄ and Hz.

Suitable PVD processes can, for example, be performed at a temperature of about 30 to about 400 degrees Celsius, at a pressure of about 1 to about 1000 mTorr. Suitable process gases include N₂.

In embodiments wherein the barrier layer 206 is a TiAlC layer, the TiAlC layer can be deposited by a suitable ALD process at a temperature of about 300 to about 450 degrees Celsius, at a pressure of about 1 to about 50 Torr. Suitable Ti precursors include TiCl₄ and TDMAT. Suitable Al precursors include TEA, TMA, and DMAH.

Optionally, after deposition of the above-described Co film or the Ru film, an annealing process can be performed at a temperature of greater than about 400 degrees Celsius in a hydrogen gas (H₂) environment held at about 1 to about 50 Torr for about 1 to about 30 minutes. The annealing process can be performed in the same process chamber, or in a separate chamber configured to perform the annealing process.

A summary of exemplary processes and process conditions is shown in the below table.

TABLE 1

| Process | Temp | Pressure | Precursors |
|---|---|---|---|
| CVD Al | 120-180 C. | 1-50 Torr | Triethylaluminum (TEA); |
| | | | dimethylaluminum hydride |
| | | | (DMAH); |
| | | | trimethylaluminum (TMA) |
| ALD Ti | 100-400 C. | 1-50 Torr | TiCl₄, CHD |
| CVD Ti | 300-700 C. | 1-200 Torr | TiCl₄, H₂, plasma |
| ALD TiAlC | 300-450 C. | 1-50 Torr | Ti: TiCl₄, TDMAT |
| | | | Al: TEA, TMA, DMAH |
| CVD Co | 100-300 C. | 1-50 Torr | CCTBA (dicobalt |
| | | | hexacarbonyl tert- |
| | | | butylacetylene) |
| ALD Mo | 400-600 C. | 1-50 Torr | Mo: MoF₆, MoCl₅, |
| | | | MoO₂Cl₂, MoOCl₄ |
| | | | Reactant: H₂, CHD |
| ALD MoN | 400-600 C. | 1-50 Torr | Mo: MoF₆, MoCl₅, |
| | | | MoO₂Cl₂, MoOCl₄; |
| | | | Reactant: H₂, CHD |

In some embodiments, the deposition of the films for the metal layer 208 and the barrier layer 206 can be performed in standalone processing chambers. Alternatively and advantageously, the deposition of the films for the metal layer 208 and the barrier layer 206 can be integrated within a multi-chamber processing system (e.g., a cluster tool), such as the line of ENDURA® processing tools available from Applied Materials, Inc., of Santa Clara, Calif.

While FIG. 2A depicts a gapfill in a general semiconductor structure according to the present disclosure, FIGS. 2B-2F depict more particular exemplary embodiments of semiconductor structures according to the present disclosure.

FIGS. 2B and 2C depict exemplary FinFET structures 200B, 200C, wherein processes in accordance with the present disclosure can be used for the gate fill portion of the fabrication of the FinFET structure.

FIG. 2D depicts a portion of a gate all around (GAA) structure 200D, wherein processes in accordance with the present disclosure can be used for the metal gate fill portion of the fabrication of the GAA structure.

FIGS. 2E and 2F respectively depict a p-type metal oxide semiconductor (PMOS) stack 200E and an n-type metal oxide semiconductor (NMOS) stack 200F, wherein processes in accordance with the present disclosure can be used in the fabrication of the PMOS and/or NMOS stacks.

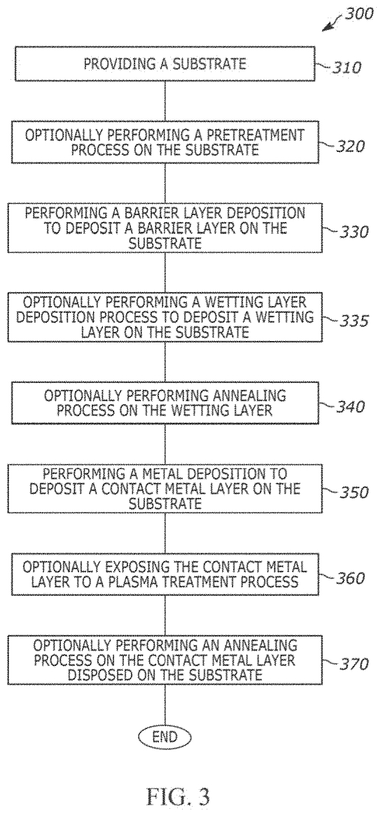

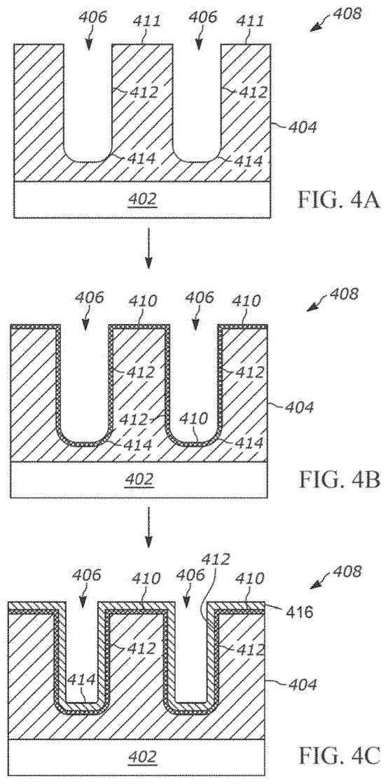

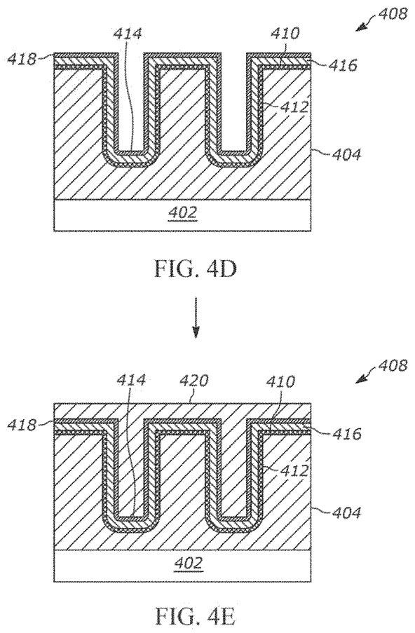

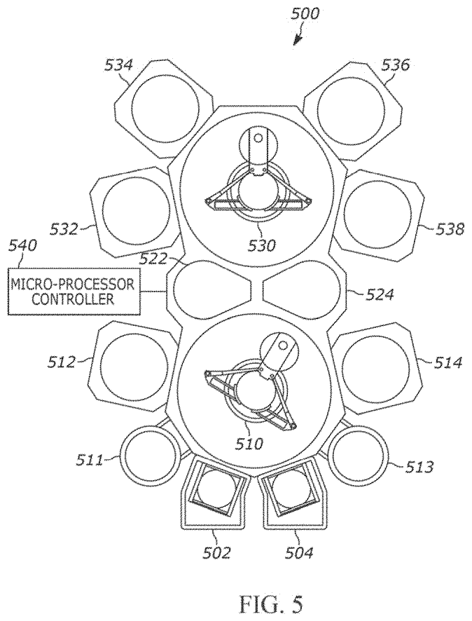

FIG. 3 is a flow diagram of a method 300 which can be employed to make a semiconductor device structure on a substrate in accordance with embodiments of the present disclosure, such as the embodiments shown in FIGS. 2A-2F. The method 300 may correspond to fabrication stages depicted in FIGS. 4A-4E. For illustrative purposes, the method of FIG. 3 is generally provided with reference to a CVD, ALD, or PVD deposited barrier layer and/or metal contact layer.

The method 300 may start at block 310 by providing a substrate, such as the substrate 402 depicted in FIG. 4A, into a processing chamber. The substrate 402 shown in FIG. 4A includes a semiconductor device structure 408 (e.g., such as a gate structure or other structures configured to form a contact structure) formed on the substrate 402.

A silicon layer 404 can be formed on the substrate 402 having features 406 formed therein. The features 406 (which may be a contact opening, contact via, contact trench, contact channel or the like) can be formed in the device structure 408 and have sidewalls 412 and a bottom 414 which form an open channel to expose the underlying silicon layer 404. The silicon layer 404 may include any suitable layers such as a single silicon layer or a multiple layer film stack having at least one silicon layer formed therein. In an embodiment wherein the silicon layer 404 is in the form of a single layer, the silicon layer 404 may be a silicon oxide layer, an oxide layer, a silicon nitride layer, a nitride layer, a silicon oxynitride layer, a titanium nitride layer, a polysilicon layer, a microcrystalline silicon layer, a monocrystalline silicon, a doped polysilicon layer, a doped microcrystalline silicon layer, or a doped monocrystalline silicon.

In an embodiment wherein the silicon layer 404 is a film stack, the stack may include a composite oxide and nitride layer, at least one or more oxide layers sandwiching a nitride layer, and combinations thereof. Suitable dopants doped in the silicon layer 404 may include p-type dopants and n-type dopants, such as boron (B) containing dopants or phosphine (P) containing dopants.

In embodiments wherein the silicon layer 404 is in form of a multiple film stack having at least one silicon containing layer, the silicon layer 404 may include repeating pairs of layers including a silicon layer and a dielectric layer. In embodiments, the silicon layer 404 may include a polysilicon layer and/or other metal materials and/or a dielectric layer disposed therein. Suitable examples of the dielectric layer may be selected from a group consisting of an oxide layer, silicon oxide layer, a silicon nitride layer, a nitride layer, titanium nitride layer, a composite of oxide and nitride layer, at least one or more oxide layers sandwiching a nitride layer, and combinations thereof, among others.

Prior to transferring the substrate 402 into the processing chamber at block 310, a pre-cleaning process, at block 320, may be optionally performed to treat substrate surfaces 411, sidewalls 412 and bottoms 414 of the openings/features 406 to remove native oxides or other sources of contaminants. Removal of native oxides or other sources of contaminants from the substrate 402 may provide a low contact resistance surface to form a good contact surface for forming a barrier layer.

The pre-cleaning process, at block 320, may include supplying a pre-cleaning gas mixture into a pre-cleaning chamber. The pre-cleaning chamber may be a Preclean PCII, PCXT or Siconi™ chambers which are available from Applied Materials, Inc., Santa Clara, Calif. The pre-cleaning process may include supplying a cleaning gas mixture into the pre-cleaning chamber to form a plasma from the pre-cleaning gas mixture for removing the native oxide. In embodiments, the pre-cleaning gas mixture can be a mixture of ammonia and nitrogen trifluoride gases. The amount of each gas introduced into the processing chamber may be varied and adjusted to accommodate, for example, the thickness of the native oxide layer to be removed, the geometry of the substrate being cleaned, the volume capacity of the plasma, the volume capacity of the chamber body, as well as the capabilities of the vacuum system coupled to the chamber body.

Also at block 320, a pretreatment process may be optionally performed to pre-treat the substrate surface 411, thus forming a treated surface region 410 on the substrate surface 411, sidewalls 412 and bottoms 414 of the features 406 in the silicon layer 404, as shown in FIG. 4B. The pretreatment process at block 320 may be performed to alter the surface bonding structure of the silicon layer 404, thereby providing a surface having a good absorption ability to promote adherence of metallic atoms provided from the subsequent barrier layer deposition process. A pre-treatment gas mixture may include at least a hydrogen containing gas, such as H2, H2O, H2O2, or the like. An inert gas, such as Ar, He, Kr, and the like, may also be supplied into the pre-treatment gas mixture.

At block 330, a barrier layer deposition process may be performed to deposit a barrier layer 416 on the substrate, and/or on the treated surface region 410, as shown in FIG. 4C. The barrier layer 416 may prevent diffusion of the contact metal layer to the junction material on the substrate, typically a silicon or silicon germanium compound. The barrier layer 416 can be deposited by atomic layer deposition (ALD), chemical vapor deposition (CVD), plasma enhanced CVD (PECVD), or physical vapor deposition (PVD). In embodiments, the barrier layer 416 may have a thickness within a range from about 2 Å to about 100 Å, or from about 3 Å to about 80 Å, or from about 4 Å to about 50 Å.

At block 335, an optional wetting layer deposition to deposit a wetting layer 418 on the substrate 402 may be carried out, as shown in FIG. 4D. The wetting layer 418 can be deposited over the barrier layer 416. The wetting layer can be deposited by a process selected from PVD Co, CVD TiN, PVD TiN, CVD Ru, PVD Ru, nitridation of PVD Ti, or combinations thereof.

In embodiments using a CVD process to deposit the wetting layer 418, a desired precursor gas is provided to the chamber and may be further provided in the presence of a carrier gas.

In embodiments using a PVD process to deposit the wetting layer 418, a target comprising the desirable material to be deposited is provided and a PVD process is performed to deposit a PVD wetting layer. In some embodiments, the wetting layer comprises PVD TiN. In such embodiments, a Ti target is provided and bombarded with ions to sputter Ti to deposit the wetting layer 418 over the barrier layer 416. A nitridation process using a nitrogen containing precursor, such as NH3, in the presence of a plasma is performed on the PVD Ti layer to form the TiN wetting layer 418. In some embodiments, the wetting layer 418 comprises a nitrided Ti layer and only the top few angstroms of titanium are converted to a TiN compound.

In some embodiments, the wetting layer 418 is PVD Co. In such embodiments, a Co target is provided and bombarded with ion to sputter co to deposit the wetting layer 418 over the barrier layer 416. In the embodiment using PVD Co, RF power is provided at a frequency from about 5000 W to about 6000 W. A power of the PVD Co process is provided from about 400 W to about 600 W and the pressure of the chamber while performing the PVD Co process is from about 50 mTorr to about 150 mTorr.

At block 340, an optional annealing process on the wetting layer 418 can be performed. The annealing process may reduce surface roughness of the wetting layer 418, increase grain size of the crystalline structure, and reduce impurities, such as carbon, that may be present in the wetting layer 418. The annealing process can be performed at a temperature of between about 200 degrees C. to about 500 degrees C. In embodiments, the annealing process can be performed for a duration of between about 10 seconds to about 1000 seconds.

At block 350, a contact metal deposition process may be performed in the processing chamber to deposit a metal contact layer 420, as shown in FIG. 4E. The metal contact layer 420 may be deposited using a cyclic deposition process. The metal contact layer 420 can thereby fill the feature 406 without a seam therein.

The metal contact layer 420 may be deposited using a multi-step deposition process comprising multiple cycles of performing a cyclic metal deposition process to deposit the metal contact layer 420. In embodiments, a thickness of the metal contact layer 420 can be less than 50% of the feature diameter (critical dimension) of the smallest feature to be filled. In embodiments, the metal contact layer 420 may have a thickness within a range from about 20 Å to about 200 Å.

In embodiments, the cyclic metal deposition process can be performed to partially fill a feature to less than half of the feature diameter followed by an optional anneal process at block 350. The cyclic deposition process followed by an optional anneal could then be repeated to deposit until the metal contact layer 420 achieves a predetermined thickness. In some embodiments, the metal contact layer 420 may be deposited to completely fill the feature in a single, non-cyclic deposition process. In such embodiments, the metal contact layer 420 may then be optionally annealed.

At block 360, the metal contact layer 420 may optionally undergo a plasma treatment process. The plasma treatment process may provide a process gas, such as H2, to the chamber and applying an RF current to form the process gas into a plasma. In an embodiment, the frequency of the RF current is between about 200 W and about 800 W. The plasma treatment process may be performed for about 1 second to about 60 seconds. In an embodiment, the substrate 402 may be heated to a temperature of between about 100 degree C. to about 200 degree C. to further reduce surface roughness of the metal contact layer 420 and reduce the percentage of impurities that may be present in the metal contact layer 420.

At block 370, an annealing process on the metal contact layer 420 may be optionally performed. The annealing process may reduce surface roughness of the metal contact layer 420 and reduce impurities, such as carbon, that may be present in the metal contact layer 420. Further the annealing process may increase crystalline grain size which results in lower resistivity, resulting in improved integrated circuit performance. The annealing process can be performed at a temperature of between about 200 degrees C. to about 500 degrees C. The annealing process may be performed in a chamber environment where an inert gas, such as argon, and a process gas, such as H2, are provided in the chamber. In an embodiment, the annealing process can be performed between about 30 seconds and about 90 seconds.

FIG. 5 depicts a schematic top-view diagram of an illustrative multi-chamber processing system 500 that can be adapted to perform the processes as disclosed hereinabove. The multi-chamber processing system 500 includes multiple processing chambers configured to perform different processes incorporated into the multi-chamber processing system 500.

The multi-chamber processing system 500 includes one or more load lock chambers 502, 504 for transferring substrates into and out of the multi-chamber processing system 500. Typically, since the multi-chamber processing system 500 is under vacuum, the load lock chambers 502, 504 can “pump down” the substrates being introduced into the multi-chamber processing system 500. A first robot 510, disposed in a first transfer chamber, can transfer the substrates between the load lock chambers 502, 504, and a first set of one or more substrate processing chambers such as processing chambers 511, 512, 513, 514. Each processing chamber 511, 512, 513, 514 is configured to perform at least one substrate processing operation, such as an etching process, a treatment process, a deposition process (such as ALD, CVD, PECVD, PVD, or the like), degas, pre-cleaning, orientation and other substrate processes including processes of the present disclosure.

In some embodiments, the first robot 510 can also transfer substrates to/from one or more pass-through chambers 522, 524. The pass-through chambers 522, 524 can be used to maintain ultra-high vacuum conditions while allowing substrates to be transferred to a second transfer chamber within the multi-chamber processing system 500. A second robot 530 is disposed in the second transfer chamber and can transfer the substrates between the pass-through chambers 522, 524 and a second set of one or more processing chambers 532, 534, 536, 538. The processing chambers 532, 534, 536, 538 are configured to perform one or more specific substrate processes including the processes described herein as well as other suitable processes that may be performed prior to or subsequent to the processes disclosed herein. For example, at least one processing chamber 532, 534, 536, 538 is configured to perform a substrate processing operation, such as a deposition process (for example, ALD, CVD, PECVD, PVD, or the like), in accordance with the methods described herein.

Any of the processing chambers 511, 512, 513, 514, 532, 534, 536, 538 can be removed from the multi-chamber processing system 500 if not necessary for a process to be performed by the multi-chamber processing system 500.

In some embodiments, the multi-chamber processing system 500 includes at least one first deposition chamber configured to deposit a first layer atop a substrate and within a feature formed in the substrate, such as the barrier layer 206 described above. In some embodiments, the multi-chamber processing system 500 further includes at least one a second deposition chamber configured to deposit a metal fill layer, such as the metal fill layer 208 described above. For example, the first deposition chamber and the second deposition chamber can be one of an ALD chamber, a CVD chamber, a PECVD chamber, a PVD chamber, or the like, specifically configured to deposit one or more of the materials described above. In some embodiments, for example when Ru or Co films are being used, one or more of the processing chambers of the multi-chamber processing system 500 can be an anneal chamber configured to perform the above-described anneal process on the deposited Co and Ru films.

A micro-processor controller 540 may be provided and coupled to various components of the multi-chamber processing system 500 to control the operation thereof. The controller 540 includes a central processing unit (CPU), a memory, and support circuits. The controller 540 may control the multi-chamber processing system 500 directly, or via other computers (or controllers) associated with particular process chamber and/or support system components. The controller 540 may be one of any form of general-purpose computer processor that can be used in an industrial setting for controlling various chambers and sub-processors. The memory, or computer readable medium, of the controller 540 may be one or more of readily available memory such as random-access memory (RAM), read only memory (ROM), floppy disk, hard disk, optical storage media (e.g., compact disc or digital video disc), flash drive, or any other form of digital storage, local or remote. The support circuits are coupled to the CPU for supporting the processor in a conventional manner. These circuits include cache, power supplies, clock circuits, input/output circuitry and subsystems, and the like. Inventive methods as described herein may be stored in the memory as software routine that may be executed or invoked to control the operation of the multi-chamber processing system 500, or the individual processing chambers coupled thereto, in the manner described herein. The software routine may also be stored and/or executed by a second CPU (not shown) that is remotely located from the hardware being controlled by the CPU.

While the foregoing is directed to embodiments of the present disclosure, other and further embodiments of the disclosure may be devised without departing from the basic scope thereof.

We claim:

1. A method of filling a feature in a semiconductor structure, comprising:
forming a barrier layer in the feature by one of atomic layer deposition (ALD), chemical vapor deposition (CVD), or physical vapor deposition (PVD);
wherein the barrier layer is one of cobalt (Co), molybdenum (Mo), molybdenum nitride (MoN) plus Mo, titanium (Ti), titanium aluminum carbide (TiAlC), or titanium nitride (TiN); and
forming a metal layer in the feature and over the barrier layer by one of ALD or CVD;
wherein the metal layer is one of aluminum (Al), Co, Mo, ruthenium (Ru), or tungsten (VV).

2. The method of claim 1, wherein forming the barrier layer is by ALD and the barrier layer is one of Mo, MoN plus Mo, Ti, TiAlC, or TiN.

3. The method of claim 1, wherein forming the barrier layer is by CVD and the barrier layer is one of Co or Ti.

4. The method of claim 1, wherein forming the barrier layer is by PVD and the barrier layer is Ti.

5. The method of claim 1, wherein forming the metal layer is by ALD and the metal layer is one of Mo or W.

6. The method of claim 1, wherein forming the metal layer is by CVD and the metal layer is one of Al, Co, or Ru.

7. The method of claim 1, wherein the semiconductor structure is one of a fin field-effect transistor (FINFET), a gate-all-around transistor (GAA), a p-type metal oxide semiconductor (PMOS) or an n-type metal oxide semiconductor (NMOS).

8. A gapfill in a feature of a semiconductor structure, comprising:
a barrier layer in the feature;
wherein the barrier layer is one of:
molybdenum (Mo), molybdenum nitride (MoN) plus Mo, titanium (Ti), titanium aluminum carbide (TiAlC), or titanium nitride (TiN), with each having been formed by atomic layer deposition (ALD); or
cobalt (Co) or Ti, with each having been formed by chemical vapor deposition (CVD), and
a metal layer in the feature and over the barrier layer;
wherein the metal layer is one of:
Mo or tungsten (W), with each having been formed by ALD; or
aluminum (Al), Co, or ruthenium (Ru), with each having been formed by CVD;
wherein the metal layer is seamless.

9. The gapfill of claim 8, wherein:
the barrier layer is Mo; and
the metal layer is Al.

10. The gapfill of claim 8, wherein:
the barrier layer is MoN plus Mo; and
the metal layer is Al.

11. The gapfill of claim 8, wherein:
the barrier layer is Ti, and
the metal layer is Al.

12. The gapfill of claim 8, wherein:
the barrier layer is TiAlC, and
the metal layer is one of Al, Co, Mo, or Ru.

13. The gapfill of claim 8, wherein:
the barrier layer is TiN; and
the metal layer is one of Co, Mo, Ru, or W.

14. The gapfill of claim 8, wherein:
the barrier layer is Co; and
the metal layer is Al.

15. The gapfill of claim 8, wherein the semiconductor structure is one of a fin field-effect transistor (FINFET), a gate-all-around transistor (GAA), a p-type metal oxide semiconductor (PMOS) or an n-type metal oxide semiconductor (NMOS).

16. A system for forming a gapfill in a feature of a semiconductor structure, comprising:
an apparatus configured to form—by one of atomic layer deposition (ALD), chemical vapor deposition (CVD), or physical vapor deposition (PVD)—in the feature a barrier layer that is one of cobalt (Co), molybdenum (Mo), molybdenum nitride (MoN) plus Mo, titanium (Ti), titanium aluminum carbide (TiAlC), or titanium nitride (TiN); and
an apparatus configured to form—by one of ALD or CVD—in the feature and over the barrier layer a metal layer that is one of aluminum (Al), Co, Mo, ruthenium (Ru), or tungsten (W);
wherein the barrier layer and the metal layer are the gapfill;
wherein the gapfill is seamless.

17. The system of claim 16, wherein the semiconductor structure is one of a fin field-effect transistor (FINFET), a gate-all-around transistor (GAA), a p-type metal oxide semiconductor (PMOS) or an n-type metal oxide semiconductor (NMOS).

18. The system of claim 16, further comprising:
an apparatus configured to anneal the metal layer.

19. The system of claim 16, further comprising:
an apparatus configured to form a wetting layer between the barrier layer and the metal layer.

20. The system of claim 16, further comprising:
an apparatus configured to expose the metal layer to a plasma treatment process.
